(19) United States
(12) Patent Application Publication
(10) Pub. No.: US 2006/0273694 A1
(43) Pub. Date: Dec. 7, 2006

(54) Low temperature conductive coating for piezoceramic materials

(75) Inventor: Carl C. Petersen, Mentor, OH (US)

Correspondence Address: James A. Hudak, Esq., Suite #304, 29425 Chagrin Blvd., Cleveland, OH, 44122, US

(73) Assignee: Channel Products, Inc.

(21) Appl. No.: 11/446,093

(22) Filed: Jun. 2, 2006

Related U.S. Application Data
(60) Provisional application No. 60/687,632, filed on Jun. 3, 2005.

(51) Int. Cl. H01L 41/04

(52) U.S. Cl. 310/340

(57) ABSTRACT

A conductive coating for piezoceramic materials is disclosed. The conductive coating is comprised of polymers, and one or more of the following metals: nickel, gold, copper, tin, brass, aluminum, or any combination thereof. The conductive coating is applied to the piezoceramic materials by commonly used methods and, after curing, forms a permanent, resilient and conductive surface possessing excellent adhesive properties and a surface conducive to solder bonding with conventional Sn/Pb solder alloys. Since the curing temperature of the conductive coating is less than the Curie temperature of the piezoceramic material, de-poling of the piezoceramic material does not occur during the process of applying the conductive coating.

### TECHNICAL FIELD

The present invention relates, in general, to a coating for piezoceramic materials and, more particularly, to a low temperature conductive coating for such materials.

### BACKGROUND ART

Historically, piezoelectric materials are commonly plated with silver, nickel, gold or copper metallic surfaces. The least complicated and most widely used process is the application of silver plate which is applied in paste form to the piezoceramic material and then fired in an oven at approximately 600° C. to melt a thin layer of silver onto the surface of the piezoceramic material. Some typical lower temperature processes utilized to deposit (or plate) nickel, gold and copper onto the piezoceramic material are performed in chemical baths commonly referred to as “electro-less” or “electro-chemical” processes. Other low temperature methods include vapor deposition and sputtering, which are widely used and accepted in this industry. The least complicated procedure is the fired silver method which is usually the least costly process. A disadvantage of the silver plate is a silver plated surface requires a special solder alloy that includes some silver in the alloy to produce an effective solder joint between the silver plated piezoceramic material and typical termination materials, such as nickel, gold, copper, and the brasses.

In general, it is more difficult and less desirable to use silver solder in solder bonding processes than the more common Tin/Lead (Sn/Pb) solders, such as the eutectic and 60/40 alloys. The Sn/Pb solder alloys more readily bond to common circuit board components and wire. Since these solder alloys do not bond well to silver plated surfaces, it is necessary to consider the use of nickel, gold or copper plating on piezoceramic materials.

Since the fired silver method has the aforementioned disadvantages and the current alternative plating processes for nickel, gold or copper are more complex, costly, and require more environmental regulations, it is desirable to develop a lower temperature and less complex process for applying a nickel, gold or copper plate to piezoceramic materials.

### SUMMARY OF THE INVENTION

The present invention solves the problems associated with the prior art methods of applying nickel, gold, copper, tin, brass, or aluminum plate to piezoceramic materials, and other problems, by providing a conductive substance consisting of polymers, and one or more of the following metals: nickel, gold, copper, tin, brass, aluminum, or any combination thereof. This conductive substance may be applied to piezoceramic materials by common industry methods. After the substance has been applied to the piezoceramic material, it may be cured at approximately 150-200° C. forming a permanent, resilient and conductive surface that possesses excellent adhesive properties. Since the curing temperature of the conductive coating is much less than the Curie temperature of the piezoceramic material, de-poling of the piezoceramic material does not occur. The same approach for coating piezoceramic material may also be used for coating piezoceramic shear plates.

### DESCRIPTION OF THE PREFERRED EMBODIMENT

The present invention involves an alternative low temperature plating process to coat piezoceramic materials with a conductive substance consisting of polymers, and one or more the following metals: nickel, gold, copper, tin, brass, aluminum, or any combination thereof, in an appropriate diluent. This conductive substance may be applied to piezoceramic materials by common industry methods, such as screen printing, spraying, brushing or dipping, etc. After the substance has been applied to the piezoceramic material, it may be cured at approximately 150-200° C. After curing, the surface coating formed is a permanent, resilient, conductive, and solderable surface that possesses excellent adhesion to piezoceramic materials.

The advantages of this process and coating are numerous. For example, any metallic element or a combination of metallic elements may be incorporated into the polymeric adhesive binder material, thus allowing the selection of the most effective metal within the coating in order to produce superior solder bonds in the specific application. In addition, the curing temperature of this conductive coating is much less than the Curie temperature of the piezoceramic materials, thus, providing an inexpensive means to plate a piezoceramic material after it has been electrically poled without de-poling the material. Also, the process of applying this conductive coating to piezoceramic materials involves less process complexity and lower manufacturing costs than electro-less chemical, electrochemical, sputtering, vapor phase deposition, and other processes currently utilized in the industry. Furthermore, the conductive coating, once applied to piezoceramic materials, produces a corrosion resistant surface due to the metal powder or flakes that are embedded in the polymeric binder material protecting the piezoceramic material from the atmosphere.

The use of a low temperature curing conductive coating may also be employed in the fabrication of a piezoceramic shear plate. The fabrication of such a shear plate is normally performed in the following manner. Piezoceramic powder is pressed into a geometric form, such as a plate or disc. Next, the piezoelectric forms are placed in a high fire oven at approximately 2300° F. Silver electrodes are applied to two (2) oppositely disposed surfaces of the forms by screen-printing a silver paste onto the surfaces. The plates are then placed in an oven at about 600° C. to fuse the silver onto the piezoceramic surfaces. The piezoceramic plates are then electrically poled by applying a DC voltage to the silver electrodes. The silver electrodes are then removed by grinding or cutting them off the silver plated surfaces. The low temperature conductive coating of the present invention can then be utilized by applying it to two (2) oppositely disposed surfaces on the piezoceramic plate that are in an orientation perpendicular to the original silver plated surfaces. Once the conductive coating has been cured, the resulting product is a piezoelectric shear plate. This is also commonly referred to in the industry as a d₁₅ plate, or d₁₅ mode shear plate. The d refers to a material constant in units of coulombs/newton, or meters/volt. The subscripts refer to the position of electrodes and direction of applied stress or induced strain. Specifically, the subscript 1 indicates that the electrodes are perpendicular to axis 1; the subscript 5 indicates that applied stress, piezoelectrically induced strain is in shear form around axis 2. The predominant feature of this process is that the temperature of the coating process is lower than the Curie temperature of the piezoceramic material permitting the application of the secondary electrodes without de-poling the ceramic material. De-poling occurs when a piezoelectric material is subjected to a temperature at or above the Curie temperature of the piezoceramic material. It should be noted that the Curie temperature is a constant that is associated with each piezoelectric material. Once a piezoelectric material has been de-poled, the material no longer exhibits piezoelectric properties. Since a low temperature plating process is required for applying secondary electrodes to fabricate a shear plate, the only presently available alternatives are costly methodologies, such as chemical baths, vapor phase deposition and sputtering. The coating process of the present invention is a less complex and less costly approach for fabricating a piezoceramic shear plate. It should be noted that this coating process can also be used in the formation of other shear mode part geometries, such as shear rings, tubes, and discs, etc

In addition to shear mode piezoceramic elements, the coating process of the present invention may be utilized in the fabrication of d₃₃ mode (or compression mode) piezoceramic plates, discs, and rings. As previously mentioned, the d refers to a material constant in units of coulombs/newton, or meters/volt, and the subscripts refer to the position of electrodes and direction of applied stress or induced strain. Specifically, the first subscript 3 indicates that the electrodes are perpendicular to axis 3: the second subscript 3 indicates that applied stress (or piezoelectrically induced strain) is in the axis 3 direction. In addition to compression mode (d₃₃ mode) piezoceramic elements, the coating process of the present invention may be utilized in the fabrication of d₃₁ mode (or length expander mode) piezoceramic plates, discs, and rings. Here again, the d refers to a material constant in units of coulombs/newton, or meters/volt, and the subscripts refer to the position of electrodes and direction of applied stress or induced strain. Specifically, the subscript 3 indicates that the electrodes are perpendicular to axis 3: the subscript 1 indicates that applied stress (or piezoelectrically induced strain) is in the axis 1 direction.

Certain modifications and improvements will occur to those skilled in the art upon reading the foregoing. It is understood that all such modifications and improvements have been deleted herefrom for the sake of conciseness and readability, but are properly within the scope of the following claims.

I claim:

1) A conductive coating for a piezoceramic material comprising at least one polymer and at least one material from the group consisting of nickel, gold, copper, tin, brass, and aluminum.

2) The conductive coating as defined in claim 1 wherein the curing temperature of the conductive coating is less than the Curie temperature of the piezoceramic material to which the conductive coating has been applied.

3) The conductive coating as defined in claim 1 wherein the coating provides an appropriate mix of metallic and polymeric materials permitting the solder bonding process and tin/lead alloys to be used to bond thereto.

4) The conductive coating as defined in claim 1 wherein the coating is utilized in the fabrication of a d₃₃ mode piezoceramic plate.

5) The conductive coating as defined in claim 1 wherein the coating is utilized in the fabrication of a d₃₃ mode piezoceramic disc.

6) The conductive coating as defined in claim 1 wherein the coating is utilized in the fabrication of a d₃₁ mode piezoceramic plate.

7) The conductive coating as defined in claim 1 wherein the coating is utilized in the fabrication of a d₃ mode piezoceramic disc.

8) The conductive coating as defined in claim 1 wherein the coating is utilized in the fabrication of a d₁₅ mode piezoceramic shear plate

9) The conductive coating as defined in claim 1 wherein the coating is utilized in the fabrication of a d₁₅ mode piezoceramic shear disc.

10) The conductive coating as defined in claim 1 wherein the coating is utilized in the fabrication of a d₁₅ mode piezoceramic shear ring.
